(19) United States
(12) Patent Application Publication
(10) Pub. No.: US 2025/0321301 A1
(43) Pub. Date: Oct. 16, 2025

(54) MEASUREMENT APPARATUS AND MEASUREMENT METHOD

(71) Applicants: SUMIDA CORPORATION, Tokyo (JP); Kyoto University, Kyoto-shi, Kyoto (JP)

(72) Inventors: Yoshiharu YOSHII, Natori City (JP); Norikazu MIZUOCHI, Kyoto-shi (JP); Yuki TAKEMURA, Kyoto-shi (JP)

(21) Appl. No.: 18/560,916

(22) PCT Filed: Jun. 7, 2022
(86) PCT No.: PCT/JP2022/022923

§ 371 Date: May 23, 2024

(30) Foreign Application Priority Data
Aug. 3, 2021 (JP) 2021-127310

(51) Int. Cl. G01R 33/26; G01N 24/00; G01R 33/32

(52) U.S. Cl. CPC G01R 33/26; G01N 24/006; G01R 33/323

(57) ABSTRACT

A light receiving device 13 receives fluorescence emitted by a magnetic resonance member 1 correspondingly to excitation light and generates a fluorescence sensor signal corresponding to an intensity of the fluorescence. A CMR calculation unit 25 performs for the fluorescence sensor signal common mode rejection based on a reference sensor signal generated by receiving a reference light obtained as a branch of the excitation light and thereby generates a CMR signal. An analog-digital converter 26 digitizes the CMR signal and an analog-digital converter 27 digitizes a reference light sensor signal. The processor 31 divides the digitized CMR signal by the digitized reference light sensor signal and thereby generates a detection signal, and derives a measurement value of the measurement target field on the basis of the detection signal; and performs a noise-removal digital filter process for the digitized CMR signal or the detection signal.

### TECHNICAL FIELD

The present invention relates to a measurement apparatus and a measurement method.

### BACKGROUND ART

A magnetic measurement apparatus performs magnetic measurement with ODMR (Optically Detected Magnetic Resonance) that uses electron spin resonance of a sensing member such as a diamond structure that includes a nitrogen and a lattice defect (an NV center: Nitrogen Vacancy Center). In ODMR, in addition to a measurement target magnetic field, a static magnetic field is applied to a magnetic resonance member such as a diamond that includes such an NV center; laser light (excitation light for initialization and measurement) and microwave are also applied in accordance with a predetermined sequence; and a light intensity is detected of fluorescence emitted from the magnetic resonance member and a magnetic flux density is derived on the basis of the light intensity.

For example, in Ramsey Pulse Sequence, (a) an NV Center is irradiated with excitation light, (b) a first pi/2 pulse of microwave is applied to the NV Center, (c) a second pi/2 pulse of microwave is applied to the NV Center with a predetermined time interval tt from the first pi/2 pulse, (d) the NV Center is irradiated with excitation light, and an emitted light intensity of the NV Center is measured, and (e) a magnetic flux density is derived on the basis of the measured light intensity. Further, in Spin Echo Pulse Sequence, (a) an NV Center is irradiated with excitation light, (b) a first pi/2 pulse of microwave is applied to the NV Center at 0-degree phase of a measurement target magnetic field, (c) a pi pulse of microwave is applied to the NV Center at 180-degree phase of the measurement target magnetic field, (d) a second pi/2 pulse of microwave is applied to the NV Center at 360-degree phase of the measurement target magnetic field, (e) the NV Center is irradiated with excitation light, and an emitted light intensity of the NV Center is measured, and (f) a magnetic flux density is derived on the basis of the measured light intensity.

A sensor device performs magnetic field measurement based on nuclear magnetic resonance using a diamond sensor that includes an NV center as mentioned (see PATENT LITERATURE #1).

### CITATION LIST

### Patent Literature

PATENT LITERATURE #1: Japan Patent Application Publication No. 2019-138772.

### SUMMARY OF INVENTION

Optically Detected Magnetic Resonance based on an electron spin resonance of a sensing member is easily affected by noise because of a weak detection signal obtained from fluorescence, and in particular, noise in an irradiation light (laser light) causes low measurement accuracy.

The present invention has been conceived in view of the aforementioned problem. It is an object of the present invention to obtain a measurement apparatus and a measurement method that reduce a noise component due to irradiation light and thereby get high measurement accuracy.

A measurement apparatus according to the present invention includes: a magnetic resonance member of which an electron spin quantum state is changed correspondingly to a measurement target field, the a magnetic resonance member capable of an electron spin quantum operation with microwave; a high-frequency magnetic field generator that performs the electron spin quantum operation of the magnetic resonance member with the microwave; a light emitting device that emits excitation light with which the magnetic resonance member should be irradiated; a fluorescence light receiving device that receives fluorescence emitted by the magnetic resonance member correspondingly to the excitation light and generates a fluorescence sensor signal corresponding to an intensity of the fluorescence; a CMR calculation unit that performs for the fluorescence sensor signal common mode rejection based on a reference sensor signal generated by receiving a reference light obtained as a branch of the excitation light, and generates a CMR signal based on the common mode rejection; a first analog-digital converter that digitizes the CMR signal; a second analog-digital converter that digitizes a reference light sensor signal generated by receiving a reference light obtained as a branch of the excitation light; and a processor that divides the digitized CMR signal by the digitized reference light sensor signal and thereby generates a detection signal, and derives a measurement value of the measurement target field on the basis of the detection signal. Further, the processor performs a noise-removal digital filter process for the digitized CMR signal or the detection signal.

A measurement method according to the present invention includes the steps of: performing an electron spin quantum operation of magnetic resonance member with microwave and emitting excitation light to the magnetic resonance member in accordance with a predetermined measurement sequence, the magnetic resonance member of which an electron spin quantum state is changed correspondingly to a measurement target field and capable of electron spin quantum operation with microwave; receiving fluorescence emitted by the magnetic resonance member correspondingly to the excitation light, and generating a fluorescence sensor signal corresponding to an intensity of the fluorescence; performing for the fluorescence sensor signal common mode rejection based on a reference sensor signal generated by receiving a reference light obtained as a branch of the excitation light, and generating a CMR signal based on the common mode rejection; digitizing the CMR signal; digitizing a reference light sensor signal generated by receiving reference light obtained as a branch of the excitation light; and dividing the digitized CMR signal by the digitized reference light sensor signal and thereby generating a detection signal, and deriving a measurement value of the measurement target field on the basis of the detection signal. Further, a noise-removal digital filter process is performed for the digitized CMR signal or the detection signal.

### Advantageous Effect of Invention

By means of the present invention, obtained are a measurement apparatus and a measurement method that reduce a noise component due to irradiation light and thereby get high measurement accuracy.

### BRIEF DESCRIPTION OF DRAWINGS

FIG. 1 shows a block diagram that indicates a configuration of a measurement apparatus according to an embodiment of the present invention;

FIG. 2 shows a diagram that indicates an example of a measurement sequence;

FIG. 3 shows a diagram that explains reference light sensor signals ref1(t), ref2(t), a fluorescence sensor signal PL(t), a CMR signal CMR_SIG(t), and a detection signal SD(t);

FIG. 4 shows a diagram that indicates an example of a frequency characteristic of a window function; and

FIG. 5 shows a flowchart that explains a behavior of the measurement apparatus (i.e. a measurement method) according to the embodiment shown in FIG. 1.

### DESCRIPTION OF EMBODIMENTS

Hereinafter, an embodiment according to aspects of the present invention will be explained with reference to a drawing.

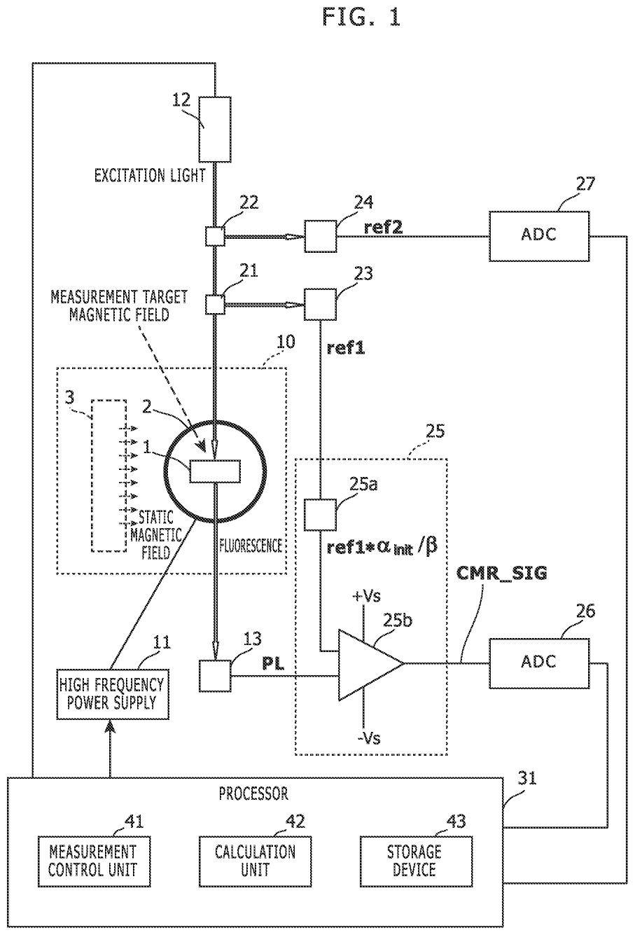

FIG. 1 shows a block diagram that indicates a configuration of a measurement apparatus according to an embodiment of the present invention. The measurement apparatus shown in FIG. 1 includes a sensor unit 10, a high-frequency power supply 11, a light emitting device 12, and a light receiving device 13.

The sensor unit 10 detects a measurement target field (e.g. a magnetic field such as an intensity, a direction, and/or the like of it) at a predetermined position (e.g. on or over a surface of a test target object). The measurement target field may be an AC (Alternating Current) field of a single frequency, an AC field that includes plural frequency components and has a predetermined period, or a DC (Direct Current) field.

In this embodiment, the sensor unit 10 includes a magnetic resonance member 1, a high-frequency magnetic field generator 2, and a magnet 3; and detects the measurement target field using ODMR.

The magnetic resonance member 1 includes a crystal structure, and is a member of which an electron spin quantum state is changed correspondingly to the measurement target field (here, magnetic field) and capable of electron spin quantum operations (based on Rabi oscillation) with microwave of frequencies corresponding to arrangement orientations of a vacancy and an impurity in a crystal lattice. Therefore, at a measurement position of the magnetic field, the magnetic resonance member 1 is arranged.

In this embodiment, the magnetic resonance member 1 is an optically detected magnetic resonance member that includes plural specific color centers (i.e. color center ensemble). Each of the plural specific color centers has a Zeeman-splittable energy level and can take plural orientations of which energy level shift amounts due to Zeeman splitting are different from each other.

Here the magnetic resonance member 1 is a member such as a diamond including plural NV (Nitrogen Vacancy) centers as specific color centers of a single type. In the NV center, the ground level is a triplet level of Ms=0, +1, −1, and levels of Ms=+1 and Ms=−1 are Zeeman-splittable. When the NV centers make transitions from excitation states of levels of Ms=+1 and Ms=−1 to the ground level, a predetermined percentage of the NV centers is accompanied by fluorescence, and a remaining g percentage of the NV centers makes a radiationless transition from the excitation state (Ms=+1 or Ms=−1) to the ground level (Ms=0).

It should be noted that color centers included in the magnetic resonance member 1 may be color centers other than NV centers.

The high-frequency magnetic field generator 2 applies microwave to the magnetic resonance member 1 and thereby performs an electron spin quantum operation of the magnetic resonance member 1. For example, the high-frequency magnetic field generator 2 is a plate coil, and includes a coil part of a substantially circular shape that outputs microwave, and terminal parts that extend from both ends of the coil part and are fixed to a substrate. The high-frequency power supply 11 generates a current for the microwave, and causes the high-frequency magnetic field generator 2 to conduct the current. This coil part conducts two flows of current parallel to each other with a predetermined gap on its both end surfaces such that the magnetic resonance member 1 is arranged between the two flows, and thereby outputs the aforementioned microwave. Here, although the coil part is a plate coil, the current flows in end surface parts of the coil part due to skin effect, and thereby the two flows of the current are formed.

In case of NV center, a color center is formed of a vacancy (hole) (V) and a nitrogen (N) as impurity in a diamond crystal, there are four possible positions (arrangement orientations of the vacancy and the nitrogen) of the nitrogen (N) adjacent to the vacancy (hole) (V) in the diamond crystal, and sub energy levels after Zeeman splitting (i.e. energy levels away from the base energy level) corresponding to these positions (i.e. four arrangement orientation) are different from each other. Therefore, in a characteristic of fluorescence intensities to frequencies of the microwave after Zeeman splitting due to the static magnetic field, four dip frequency pairs (fi+, fi−) corresponding to the orientations i (i=1, 2, 3, 4) appear differently from each other. Here, a frequency (a wavelength) of the aforementioned microwave is set correspondingly to any dip frequency among the four dip frequency pairs.

Further, the magnet 3 applies a static magnetic field (DC magnetic field) and thereby causes Zeeman splitting of the energy level of the plural specific color centers (here, plural NV centers) in the magnetic resonance member 1. Here, the magnet 3 is a ring-type permanent magnet, for example, a ferrite magnet, an alnico magnet, a samarium-cobalt magnet or the like.

In this embodiment, an application direction of the aforementioned static magnetic field is identical to an application direction of the aforementioned measurement target magnetic field, and applying the aforementioned static magnetic field gains fluorescence intensity variation at the aforementioned dip frequency and results in a high sensitivity.

Further, in this embodiment, the magnetic resonance member 1 includes plural color centers (here, NV centers) capable of electron spin quantum operations with the aforementioned microwave, and the magnet 3 applies a substantially uniform static magnetic field to a predetermined area (an irradiation area of the excitation light and the measurement light) of the magnetic resonance member 1. For example, the static magnetic field is applied such that in the predetermined area a difference or a ratio between a maximum value and a minimum value of intensity of the static magnetic field gets equal to or less than a predetermined value.

Further, a crystal in the magnetic resonance member 1 is formed and an orientation of the magnetic resonance member 1 is set, so as to cause an arrangement direction of the aforementioned vacancy and impurity to be substantially identical to a direction of the aforementioned static magnetic field (and a direction of the application magnetic field) in the magnetic resonance member 1.

Further, in this embodiment, in order to irradiate the magnetic resonance member 1 with the excitation light, an optical system from the light emitting device 12 to the magnetic resonance member 1 is installed and an optical system from the magnetic resonance member 1 to the light receiving device 13 is installed.

The light emitting device 12 includes a laser diode as a light source and using the light source, emits laser light of a predetermined wavelength as excitation light with which the magnetic resonance member 1 should be irradiated. Further, the light receiving device 13 includes a photo diode or photo transistor as photodetector, and receives fluorescence emitted by the magnetic resonance member 1 correspondingly to the excitation light and generates a fluorescence sensor signal PL corresponding to an intensity of the fluorescence. This fluorescence is converged toward the light receiving device 13 by an optical system such as compound paraboloid type condenser (CPC), for example.

Here a principle of the measurement is explained.

An intensity I of the aforementioned excitation light is a sum of an original intensity Ilaser and an intensity of a noise component Inoise, as the following formula. This noise component occurs due to a fluctuation of a power supply voltage of the light emitting device 12, a fluctuation of a light emitting amount of the light source or the like, and has a frequency in a range from about kHz-order frequency to about 100 kHz-order frequency, for example.

I=Ilaser+Inoise

Further, a level of the fluorescence sensor signal PL is basically proportional to the intensity I of the excitation light. However, at an excitation light irradiation starting time point of the measurement, the fluorescence intensity is small due to change of an electron spin quantum state by a measurement target field, and after it, the fluorescence intensity gradually increases until influence disappears of the change of the electron spin quantum state by the measurement target field. Therefore, a detection signal SD is derived as a signal that indicates the measurement target field such that the detection signal SD is proportional to a level change component αcont(t) of the fluorescence sensor signal PL due to the change of the electron spin quantum state by the measurement target field. The fluorescence sensor signal PL is expressed as the following formula.

PL(t)=α(t)×I=(αinit+αcont(t))×I=(αinit+αcont(t))×(Ilaser+Inoise)

Here, αinit is a coefficient that indicates a component proportional to the intensity I of the excitation light (a component without influence of the change of the electron spin quantum state by the measurement target field).

Meanwhile, a level ref of a reference light sensor signal of reference light as a branch of the excitation light is proportional to the intensity I of the excitation light, and therefore expressed as the following formula.

ref=ref1=ref2=β×I=β×(Ilaser+Inoise)

Here, β is a constant. ref1 and ref2 are mentioned below.

Here, common mode rejection is performed for PL(t) and thereby a CMR signal is generated. The CMR signal CMR_SIG(t) is expressed as the following formula. Consequently, regarding αinit, influence of Inoise is eliminated.

CMR_SIG(t)=PL(t)−αinit/β×ref(t)=αcont(t)×(Ilaser+Inoise)

Further, the aforementioned detection signal SD(t) is derived as the following formula. Consequently, regarding αcont(t), influence of Inoise is eliminated.

SD(t)=αcont(t)/β=CMR_SIG(t)/ref(t)

A peak value (a value at t=0) and a time-integral value of the detection signal SD(t) have correlations with an intensity of the measurement target field, and therefore, a relationship between a peak value or a time-integral value of the detection signal SD(t) and an intensity of the measurement target field is determined by an experiment or the like in advance, and an intensity of the measurement target field is derived from a peak value or a time-integral value of the detection signal SD(t) using a calculation formula or a table that indicates the relationship.

A configuration mentioned below is installed on the basis of the aforementioned measurement principle.

The measurement apparatus shown in FIG. 1 further includes light separation units 21 and 22 as optical elements on a light path of the excitation light from the light emitting device 12 to the magnetic resonance member 1. The light separation units 21 and 22 make respective branches of the excitation light as parts of the excitation light, and emit the parts of the excitation light as reference light to other directions, respectively. For example, the light separation units 21 and 22 are polarization-independent beam splitters.

Further, the measurement device shown in FIG. 1 includes light receiving devices 23 and 24 that receive the reference light and generate reference light sensor signals ref1 and ref2 (the aforementioned ref) corresponding to an intensity of the reference light.

In this embodiment, two flows of the reference light are independently generated from the excitation light, and two reference light sensor signals ref1 and ref2 are generated. The reference light sensor signal ref1 is used in the common mode rejection mentioned below, and the reference light sensor signal ref2 is digitized and used to generate the detection signal SD.

Further, the measurement apparatus shown in FIG. 1 includes a CMR calculation unit 25 as an analog calculation circuit. The CMR calculation unit 25 performs for the fluorescence sensor signal PL common mode rejection based on the reference sensor signal ref1, and generates a CMR signal CMR_SIG based on the common mode rejection. Specifically, the CMR calculation unit 25 includes a coefficient unit 25a and a differential amplifier 25b. The coefficient unit 25a multiplies the reference light sensor signal ref1 by a predetermined coefficient αinit/B. The differential amplifier 25b calculates a difference between the fluorescence sensor signal PL and an output signal ref1×□init/β of the coefficient unit 25a, and outputs the calculation result as the CMR signal CMR_SIG.

The coefficient unit 25a may be installed as a circuit, and otherwise, the coefficient unit 25a may not be installed and a gain of the light receiving device 23 may be controlled and thereby may output the reference light sensor signal multiplied by the predetermined coefficient αinit/β.

Further, the measurement apparatus shown in FIG. 1 includes analog-digital converters 26 and 27 that digitize the CMR signal CMR_SIG and the reference light sensor signal ref2, respectively; and a processor 31 that controls the measurement apparatus and performs signal processing.

The analog-digital converters 26 and 27 digitize the CMR signal CMR_SIG and the reference light sensor signal ref2 with predetermined bit widths and with predetermined sampling periods (rates), and outputs the digitized CMR signal CMR_SIG and the digitized reference light sensor signal ref2 to the processor 31.

The processor 31 includes a computer, for example, and executes a signal processing program using the computer, and thereby acts as sorts of processing units. In this embodiment, the processor 31 causes the computer to act as a measurement control unit 41 and a calculation unit 42, and includes a non-volatile storage device 43.

In the storage device 43, the signal processing program has been stored, and the computer includes a CPU (Central Processing Unit), a ROM (Read Only Memory), a RAM (Random Access Memory) and the like, and loads the signal processing program to the RAM and executes the signal processing program using the CPU, and thereby acts as the measurement control unit 41 and the calculation unit 42.

In accordance with a predetermined measurement sequence, the measurement control unit 41 (a) controls the high-frequency power supply 11 and the light emitting device 12, and (b) acquires the aforementioned digitized CMR signal CMR_SIG and reference light sensor signal ref2 and stores CMR_SIG and ref 2 into the RAM or the storage device 43 and causes the calculation unit 42 to derive a measurement value of the measurement target field.

The aforementioned measurement sequence is set in accordance with a frequency or the like of the measurement target field. For example, if the measurement target field is an AC (alternating current) field of a relatively high frequency, a Spin Echo sequence (Hahn Echo sequence) is applied as this measurement sequence. The measurement sequence is not limited to this. Further, for example, if the measurement field is an AC field of a relatively low frequency, measurement of the physical field may be performed plural times in one period of the measurement target field in accordance with Ramsey pulse sequence (i.e. a measurement sequence for a DC (Direct Current) field), and the measurement target field (intensities, waveform or the like of it) may be determined on the basis of measurement results.

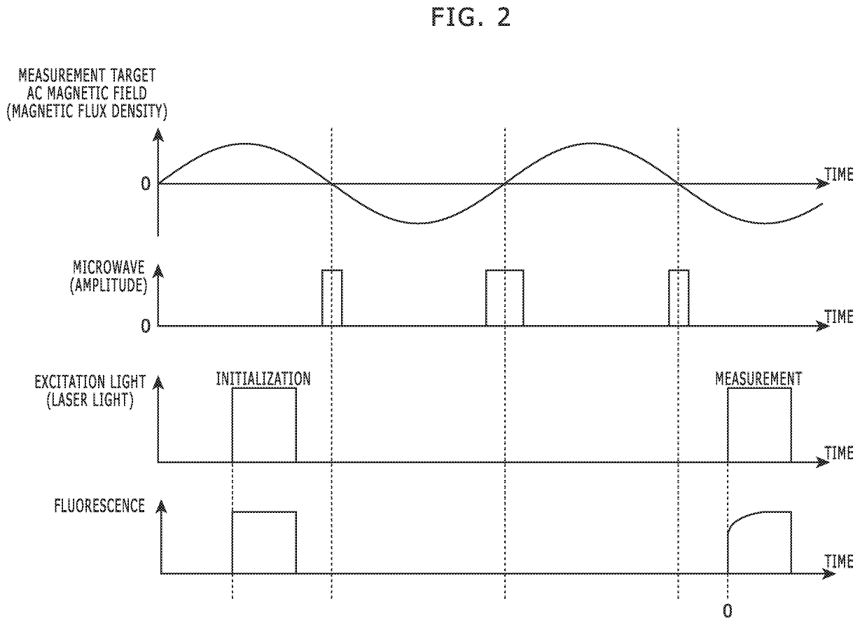

FIG. 2 shows a diagram that indicates an example of a measurement sequence. FIG. 2 indicates timings of microwave pulses and irradiation timings of the excitation light (twice for initialization and measurement) for the measurement target magnetic field in Spin Echo sequence. As shown in FIG. 2, fluorescence is detected in an irradiation period of the excitation light.

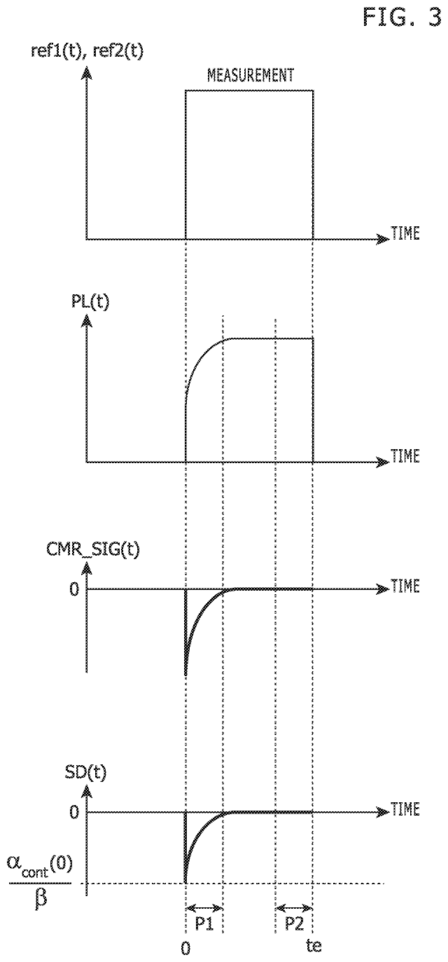

FIG. 3 shows a diagram that explains reference light sensor signals ref1(t), ref2(t), a fluorescence sensor signal PL(t), a CMR signal CMR_SIG(t), and a detection signal SD(t).

As shown in FIG. 3, the reference light sensor signals ref1(t) and ref2(t) are pulse signals of a substantially square shape in the irradiation period, and the fluorescence sensor signal PL(t) is a pulse signal that gradually raises and converges to a constant level in the irradiation period. Further, the CMR signal CMR_SIG(t) is obtained by the common mode rejection.

Further, the calculation unit 42 divides the digitized CMR signal CMR_SIG(t) by the digitized reference light sensor signal ref2(t) and thereby generates the detection signal SD(t) proportional to αcont(t), and derives a measurement value (here, a magnetic flux density, a waveform of the magnetic field or the like) of the measurement target field on the basis of the detection signal SD(t).

Furthermore, the calculation unit 42 performs a noise-removal digital filter process for the digitized CMR signal CMR_SIG(t) or the detection signal SD(t).

In this embodiment, in this digital filter process, the calculation unit 42 applies a window function to the digitized CMR signal CMR_SIG(t) or the detection signal SD(t), and thereby reduces a high frequency component (a noise component having a high frequency) in this signal. The window function is a FIR (Finite Impulse Response) filter.

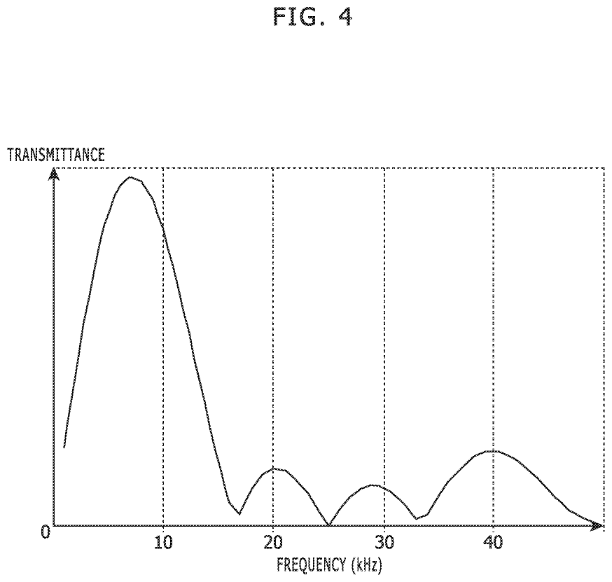

FIG. 4 shows a diagram that indicates an example of a frequency characteristic of a window function. The aforementioned window function has a frequency characteristic as shown in FIG. 4, for example, and reduces a high frequency noise component (in this case, reduces a component of about 10 kHz or higher).

Further, in this embodiment, the calculation unit 42 performs a noise removal process independently from the aforementioned digital filter process. In the noise removal process, the calculation unit 42 (a) accumulates values of the digitized CMR signal (of a predetermined sampling number) obtained plural times in a first half part of an irradiation period of the excitation light and plural times in a second half part of the irradiation period, and (b) calculates a difference between an accumulation value (a total sum or an average) of the CMR signal in the first half part and an accumulation value (a total sum or an average) of the CMR signal in the second half part and thereby removes a noise component in the CMR signal.

As shown in FIG. 3, for example, in a period P1 (a period of a predetermined time length from an irradiation staring time point (t=0)) in the first half part, values of the CMR signal of a predetermined sampling number are obtained; in a period P2 (a period of a predetermined time length to an irradiation ending time point (t=the)) in the second half part, values of the CMR signal of the predetermined sampling number are obtained; and the accumulation value of the second half part is subtracted from the accumulation value of the first half part, a value of the subtraction result is set as a value of the CMR signal and thereby a noise component in the CMR signal is restrained.

Further, in this embodiment, the analog-digital converter 26 operates at a higher rate than the analog-digital converter 27, and the analog-digital converter 27 performs digitization of a higher precision than the analog-digital converter 26.

For example, the analog-digital converter 26 converts an input analog signal to a 20-bit digital signal with 200M samples per second, and the analog-digital converter 27 converts an input analog signal to a 24-bit digital signal with 100k samples per second, for example.

The CMR signal after analog-digital conversion by the analog-digital converter 26 changes relatively quickly and therefore is sampled by the high-rate analog-digital converter 26, and as mentioned, the noise removal based on plural times of sampling is performed. On the other hand, as mentioned, the reference light sensor signal ref2 after analog-digital conversion by the analog-digital converter 27 is used for the dividing for theoretically removing influence of the noise component Inoise in the excitation light, and requires a precision corresponding to a voltage level of the term of the product of the level change component αcont(t) and the noise component intensity Inoise, relative to a voltage level of the fluorescence sensor signal PL in the detected fluorescence sensor signal PL, and therefore, the reference light sensor signal ref2 is sampled by the relatively-high-precision analog-digital converter 27.

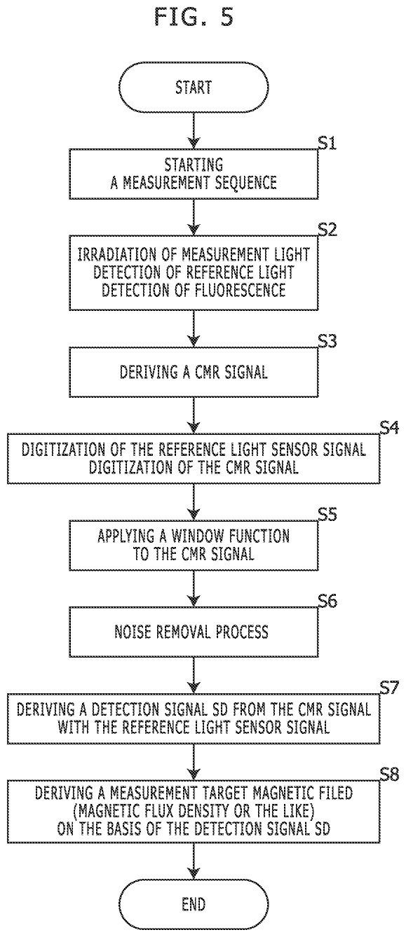

The following part explains a behavior of the measurement apparatus in this embodiment. FIG. 5 shows a flowchart that explains a behavior of the measurement apparatus (i.e. a measurement method) according to the embodiment shown in FIG. 1.

The sensor unit 10 is arranged at a measurement position of a measurement target field. The measurement may be performed at plural measurement positions while the sensor unit is moved for scanning.

Subsequently, the measurement control unit 41 causes the light emitting device 12 to emit excitation light and causes the high-frequency magnetic field generator 2 to output microwave, in accordance with a predetermined measurement sequence (in Step S1).

Consequently, in an irradiation period of the excitation light in the measurement, the fluorescence sensor signal PL (analog signal) is outputted from the light receiving device 13, and the reference light sensor signals ref1 and ref2 (analog signal) are outputted from the light receiving devices 23 and 24, respectively (in Step S2). Subsequently, the CMR signal CMR_SIG(t) based on the fluorescence sensor signal PL(t) and the reference light sensor signal ref1 is outputted by the CMR calculation unit 25, and digitized by the analog-digital converter 26 (in Steps S3 and S4). On the other hand, the reference light sensor signal ref2 is digitized by the analog-digital converter 27 (in Step S4).

When the measurement control unit 41 acquires the CMR signal CMR_SIG(t) (digital signal) and the reference light sensor signal ref2 (digital signal), the calculation unit 42 applies the window function to the CMR signal and thereby removes a high-frequency noise component (e.g. a component of 10 kHz or higher) in the CMR signal CMR_SIG(t) (in Step S5), and further performs the accumulation and the subtraction of plural-times (e.g. 1000-times) sampled values of the CMR signal CMR_SIG(t) and thereby removes a noise component of a relatively low frequency (e.g. a component of a few kHz to 10 kHz) (in Step S6).

Subsequently, the calculation unit 42 divides a value of the CMR signal obtained after the noise removal as mentioned, by a value of the reference light sensor signal ref2, and thereby derives a value of the detection signal (in Step S7), and derives a measurement value of the measurement target field at the measurement position and at the measurement timing (at a performing timing of the measurement sequence) from the value of the detection signal (in Step S7).

As mentioned, in the aforementioned embodiment, the high-frequency magnetic field generator 2 performs with microwave an electron spin quantum operation of the magnetic resonance member 1 of which an electron spin quantum state is changed correspondingly to a measurement target field and capable of an electron spin quantum operation with microwave. The light emitting device 12 emits excitation light with which the magnetic resonance member 1 should be irradiated. The light receiving device 13 receives fluorescence emitted by the magnetic resonance member 1 correspondingly to the excitation light and generates a fluorescence sensor signal corresponding to an intensity of the fluorescence. For the fluorescence sensor signal, the CMR calculation unit 25 performs common mode rejection based on a reference sensor signal generated by receiving a reference light obtained as a branch of the excitation light, and generates a CMR signal based on the common mode rejection. The analog-digital converter 26 digitizes the CMR signal and the analog-digital converter 27 digitizes a reference light sensor signal generated by receiving a reference light obtained as a branch of the aforementioned excitation light. The processor 31 divides the digitized CMR signal by the digitized reference light sensor signal and thereby generates a detection signal, and derives a measurement value of the measurement target field on the basis of the detection signal. Further, the processor 31 performs a noise-removal digital filter process for the digitized CMR signal or the detection signal.

Consequently, the aforementioned common mode rejection, the dividing, and the digital filter process restrain a noise component due to the excitation light with which the magnetic resonance member 1 is irradiated, and therefore increase measurement precision.

Further, it should be understood that various changes and modifications to the embodiments described herein will be apparent to those skilled in the art. Such changes and modifications may be made without departing from the spirit and scope of the present subject matter and without diminishing its intended advantages. It is therefore intended that such changes and modifications be covered by the appended claims.

For example, in the aforementioned embodiment, the magnetic field measurement is performed on the basis of Optically Detected Magnetic Resonance. Alternatively, temperature measurement or the like may be performed as well. In addition, a current measurement may be performed on the basis of a magnetic field obtained by the magnetic measurement.

Further, in the aforementioned embodiment, the reference light for the aforementioned dividing is made as a branch of the excitation light independently from the reference light for the common mode rejection. Alternatively, the reference light made as a branch of the excitation light for the common mode rejection may be used as the reference light for the aforementioned dividing. Furthermore, the aforementioned reference light sensor signals ref1 and ref2 are generated independently from each other. Alternatively, a single reference light sensor signal ref may be generated and used as the aforementioned reference light sensor signals ref1 and ref2.

Furthermore, in the aforementioned embodiment, the window function is applied to the CMR signal. Alternatively, the window function may be applied to the detection signal.

Furthermore, in the aforementioned embodiment, the differential amplifier 235b may be installed independently from the analog-digital converter 26 or may be built in the analog-digital converter 26.

### INDUSTRIAL APPLICABILITY

For example, the present invention is applicable to a measurement apparatus using Optically Detected Magnetic Resonance.

1. A measurement apparatus, comprising:
a magnetic resonance member of which an electron spin quantum state is changed correspondingly to a measurement target field, the magnetic resonance member capable of an electron spin quantum operation with microwave;
a high-frequency magnetic field generator that performs the electron spin quantum operation of the magnetic resonance member with the microwave;
a light emitting device that emits excitation light with which the magnetic resonance member should be irradiated;
a fluorescence light receiving device that receives fluorescence by the magnetic resonance member correspondingly to the excitation light and generates a fluorescence sensor signal corresponding to an intensity of the fluorescence;
a CMR calculation unit that performs for the fluorescence sensor signal common mode rejection based on a reference sensor signal generated by receiving a reference light obtained as a branch of the excitation light, and generates a CMR signal based on the common mode rejection;
a first analog-digital converter that digitizes the CMR signal;
a second analog-digital converter that digitizes a reference light sensor signal generated by receiving a reference light obtained as a branch of the excitation light; and
a processor that divides the digitized CMR signal by the digitized reference light sensor signal and thereby generates a detection signal, and derives a measurement value of the measurement target field on the basis of the detection signal;
wherein the processor performs a noise-removal digital filter process for the digitized CMR signal or the detection signal.

2. A measurement method, comprising the steps of:
performing an electron spin quantum operation of magnetic resonance member with microwave and emitting excitation light to the magnetic resonance member in accordance with a predetermined measurement sequence, the magnetic resonance member of which an electron spin quantum state is changed correspondingly to a measurement target field and capable of electron spin quantum operation with microwave;
receiving fluorescence emitted by the magnetic resonance member correspondingly to the excitation light, and generating a fluorescence sensor signal corresponding to an intensity of the fluorescence;
performing for the fluorescence sensor signal common mode rejection based on a reference sensor signal generated by receiving a reference light obtained as a branch of the excitation light, and generating a CMR signal based on the common mode rejection;
digitizing the CMR signal;
digitizing a reference light sensor signal generated by receiving reference light obtained as a branch of the excitation light;
dividing the digitized CMR signal by the digitized reference light sensor signal and thereby generating a detection signal, and deriving a measurement value of the measurement target field on the basis of the detection signal; and
performing a noise-removal digital filter process for the digitized CMR signal or the detection signal.

3. The measurement method according to claim 2, wherein the CMR signal is digitized by a first analog-digital converter;
the reference light sensor signal is digitized by a second analog-digital converter;
the first analog-digital converter operates at a higher rate than the second analog-digital converter; and
the second analog-digital converter performs digitization of a higher precision than the first analog-digital converter.

4. The measurement method according to claim 2, wherein the reference light sensor signal digitized and used for generation of the detection light is generated independently from the reference light sensor signal used for the common mode rejection.

5. The measurement method according to claim 2, wherein in the digital filer process, a window function is applied to the digitized CMR signal or the detection signal.

6. The measurement method according to claim 2, further comprising the steps of:
(a) accumulating values of the digitized CMR signal obtained plural times in a first half part of an irradiation period of the excitation light and plural times in a second half part of the irradiation period; and
(b) calculating a difference between an accumulation value of the CMR signal in the first half part and an accumulation value of the CMR signal in the second half part and thereby removing a noise component in the CMR signal.
